(19) United States
(12) Patent Application Publication
(10) Pub. No.: US 2008/0217163 A1
(43) Pub. Date: Sep. 11, 2008

(54) MANUFACTURING METHOD FOR A FAR-INFRARED SUBSTRATE

(75) Inventors: Yung-Sheng Lin, Taipei (TW); Han-Chang Pan, Taipei (TW); Chao-Te Lee, Taipei (TW); Ting-Kai Leung, Taipei City (TW)

Correspondence Address: VOLPE AND KOENIG, P.C., UNITED PLAZA, SUITE 1600, 30 SOUTH 17TH STREET, PHILADELPHIA, PA, 19103, US

(73) Assignees: NATIONAL APPLIED RESEARCH LABORATORIES, Taipei (TW); TAIPEI MEDICAL UNIVERSITY, Taipei City (TW)

(21) Appl. No.: 11/969,425

(22) Filed: Jan. 4, 2008

(30) Foreign Application Priority Data
Mar. 7, 2007 (TW) 096107951

(51) Int. Cl. C23C 14/34

(52) U.S. Cl. 204/192.26; 204/192.1

(57) ABSTRACT

A manufacturing method for a far-infrared (FIR) substrate is provided. The manufacturing method includes steps of providing a substrate and sputtering a FIR emission material onto at least one surface of the substrate to form a thin film.

### FIELD OF THE INVENTION

The present invention is related to a method for manufacturing a far-infrared substrate. More particularly, the present invention is related to a method for manufacturing a far-infrared thin film on the surface of the substrate by sputtering.

### BACKGROUND OF THE INVENTION

The far infrared (FIR) ray is a part of the electromagnetic spectrum from 5.6 to 1000 micron wavelength, wherein the FIR ray in the 4 to 14 micron range is optimal for growth of the animals and plants, and therefore many scientists call it “ray of life”. It was found that the FIR ray penetrates deeper into human tissues and induces a higher skin blood flow, which causes a physical phenomenon called “RESONANCE”. When the FIR ray penetrates through the skin to the subcutaneous tissues, it is transformed from light energy into heat energy and has effects of instantly invigorating cellular activities, promoting better blood circulation, improving the overall metabolism, increasing the regeneration ability of tissues, activating the immune system and so on. So far, it has been medically proved that the FIR ray has effects on curing many human diseases. Therefore, many FIR related products have been developed for the industrial applications, but the composition of the FIR materials used in these products may contain too much rare elements, which may cause the radiation harmful to health. The FIR materials used in the present invention come from natural minerals, so the usage thereof is safe and healthy.

Supposing the substrate is a textile, the methods for manufacturing a FIR textile in the prior arts are usually to blend the fiber polymer and the FIR ceramic powder together to make the FIR yarn, and then the FIR yarn is made into various FIR textile products. Besides, in the prior arts the FIR materials can be adhered to the textiles or yarn by impregnating, printing, coating, covering and laminating and so on. However, because the tensile strength of the fiber polymer decreases with an increase of the additive content and because of the nozzles were worn away by the abrasive FIR ceramic powder, the content of the FIR ceramic powder in the textile is limited. In general, the highest content of the FIR ceramic powder in the textile is less than 5%, but the FIR emissivity of the FIR ceramic powder with a percentage within this limiting range may be insufficient for effective cure. Besides, if the size of the FIR ceramic powder is too large or the fibers of the textiles are too thin, the FIR ceramic powder cannot be embedded firmly between the fibers, so that it will easily peel off after using for a period of time and the function of the FIR textiles will be lost accordingly.

Supposing the substrate material is made of a plastic film, the protective film disclosed in the Taiwan Patent No. I200886 is fabricated by a spin coating method for coating the FIR ceramic powder onto the substrate.

The method of blending the FIR ceramic powder into the fiber polymer has the disadvantage of limiting the FIR ceramic powder content. Too much FIR ceramic powder blended in the fiber polymer will cause the problem of decreasing the strength of the FIR yarn, thereby causing the production yield rate to be slow. The spin coating method is a wet process, which is complicated and needs an additional organic solvent process for preparing the ceramic slurry. The organic solvent will jeopardize the safety of the operators and it has the environment-loading problem as well.

Therefore, because of the disadvantages in the prior arts, the inventors provide a method for manufacturing a far-infrared substrate to effectively overcome the demerits existing in the prior art. The energized ion and low temperature process according to the present invention decrease the problem of the deformation of some heat-sensitive substrates. Besides, the sputtering method according to the present invention is able to achieve the purpose of forming a transparent and uniform FIR ceramic thin film on the surface of a substrate depending on necessities. The present invention will solve the drawbacks existing in the prior arts.

### SUMMARY OF THE INVENTION

In accordance with an aspect of the present invention, a manufacturing method for a far-infrared (FIR) substrate is provided. The manufacturing method comprises the steps of providing a substrate and sputtering a FIR emission material onto the substrate.

Preferably, the sputtering step comprises the steps of: (a) preparing a target containing the FIR emission material; (b) providing a vacuum chamber and configuring a sputtering source in the vacuum chamber with the target placed on the sputtering source; (c) configuring the substrate at a position opposite to the FIR emission material in the vacuum chamber; (d) introducing a reaction gas into the vacuum chamber for igniting plasma; (e) applying a current for ionizing the reaction gas; and (f) sputtering the FIR emission material on at least one surface of the substrate for forming a thin film.

Preferably, the sputtering further comprises the step of processing the surface of the substrate with an ionization pretreatment.

Preferably, the sputtering step further comprises a step of controlling a flow rate of the reaction gas in a range of 10 to 200 c.c. per minute.

Preferably, the sputtering step further comprises a step of controlling a temperature within the vacuum chamber at a temperature ranging from 25 to 100° C.

Preferably, the step (b) further comprises a step of controlling a gas pressure within the vacuum chamber in a range of 10⁻¹ to 10⁻⁴ Torr.

Preferably, the reaction gas introduced in the step (d) is one selected from a group consisting of an argon, an oxygen and a combination thereof.

Preferably, the current in the step (e) is provided by one selected from a group consisting of a direct current power, a radio frequency power, a pulse direct current power and a microwave power.

Preferably, a thickness of the thin film is ranged from 1 nm to 10 μm.

Preferably, a transmittance of the thin film in a visible light range is in a range of 60˜99%.

Preferably, the transmittance of the thin film in a visible light range is in a range of 80˜99%.

Preferably, the thin film is layered with at least one layer of the FIR emission material.

Preferably, the substrate is one selected from a group consisting of a metal, a glass, a ceramic powder and a copolymer.

Preferably, the FIR emission material comprises an aluminum oxide.

Preferably, the FIR emission material has a FIR emissivity of higher than 0.9.

In accordance with another aspect of the present invention, a manufacturing method for a far-infrared (FIR) substrate is provided. The manufacturing method comprises the steps of providing an ion bombardment pretreated substrate, placing the ion bombardment pretreated substrate and a FIR material in a space filled with a gas and applying a current to the gas for forming the FIR substrate.

Preferably, the manufacturing method further comprises the steps of filling the gas in a rate of 10 to 200 c.c. per minute, providing a temperature of the space ranged from 25 to 100° C., and providing a pressure of the space ranged from 10⁻¹ to 10⁻⁴ Torr.

Preferably, the gas is one selected from a group consisting of an argen, an oxygen, and a combination thereof, and the FIR material comprises an aluminum oxide.

Preferably, the manufacturing method further comprises a step of forming a thin layer of the FIR material on the ion bombardment pretreated substrate after the current is applied.

Preferably, a thickness of the thin layer is ranged from 1 nm to 10 μm, and a transmittance of the thin layer is ranged from 80˜99%.

The above objects and advantages of the present invention will become more readily apparent to those ordinarily skilled in the art after reviewing the following detailed descriptions and accompanying drawings, in which:

### BRIEF DESCRIPTION OF THE DRAWINGS

FIG. 1 is a diagram showing the manufacturing method for a FIR substrate according to a preferred embodiment of the present invention;

FIG. 2 is a diagram showing the surface processing method with an ion source according to the present invention;

FIG. 3 is a side view of the FIR substrate according to the present invention;

FIG. 4 is a side view of another FIR substrate according to the present invention;

FIG. 5 is a diagram showing the FIR emissivity of the FIR materials according to the present invention; and

FIG. 6 is a diagram showing the transmittance of a FIR thin film according to the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for the purposes of illustration and description only; it is not intended to be exhaustive or to be limited to the precise form disclosed.

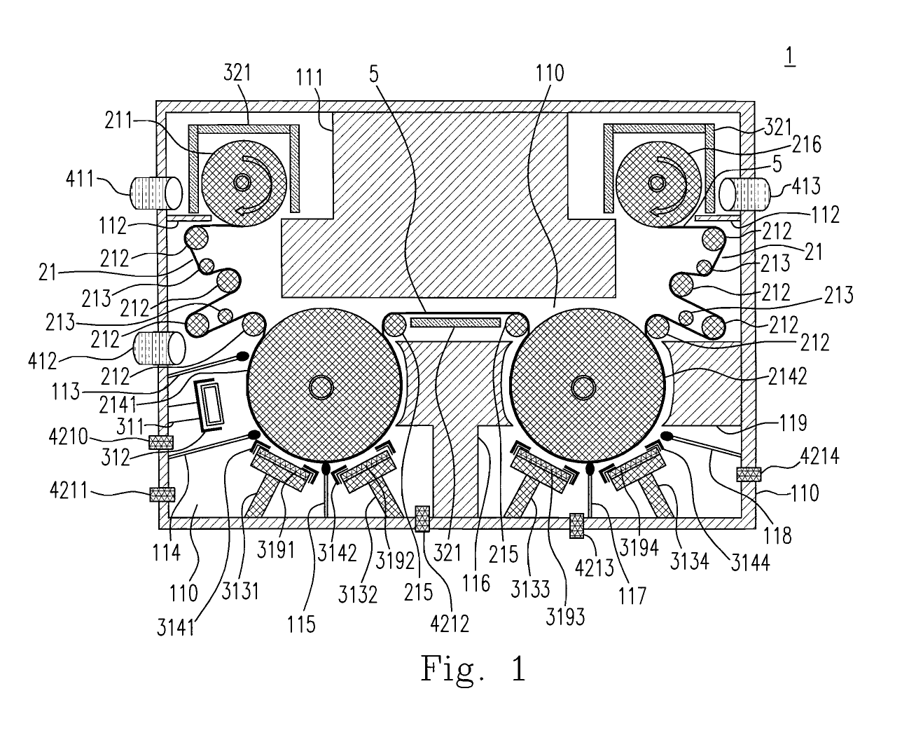

Please refer to FIG. 1, which is a diagram showing the manufacturing method for a FIR substrate according to a preferred embodiment of the present invention. As shown, the substrate 51 in this embodiment is a soft substrate, which could be made into the FIR substrate 5 via the processing device 1. The processing device 1, which can be used to automatically manufacture the FIR substrate 5, comprises a vacuum chamber 110, vacuum pumping pipes 411-413, automatic pressure controlling systems 4210-4214 configured on the vacuum chamber 110, and a plurality of sputtering components configured in the vacuum chamber 110. The vacuum chamber 110 is separated into several space by a plurality of partitions 111-119. The sputtering components configured in the vacuum chamber 110 includes a substrate rolling mechanism, a transport pulley set 21, a first sputtering drum 2141, a second sputtering drum 2142, four sputtering sources 3131-3134 separated by the partitions 114-119 and an ion source 311. The ion source 311 is configured around the first sputtering drum 2141 and the four sputtering sources 3131-3134 are configured around the first and the second sputtering drums 2141, 2142. The substrate rolling mechanism comprises a substrate-supplying pulley 211 and a substrate-receiving pulley 216. The transport pulley set 21 configured around the substrate rolling mechanism comprises two pairs of substrate transporting guide pulleys 212 and one pair of tension controlling pulleys 213, which is a pulley set for controlling the tension of the soft substrate. A polycold 321 for a condensation of the residual water vapor in the vacuum chamber 110 and maintaining a lower water vapor pressure is respectively configured around the substrate rolling mechanism and between the first and the second sputtering drums 2141, 2142.

The method for continuously manufacturing a FIR substrate 5 having the function of FIR emission according to the present invention is performed in the foregoing processing device 1. The method comprises the following steps.

A processing device 1 is prepared. The major components for automatically and continuously manufacturing the FIR substrate 5 are described above.

A substrate 51 is provided. The soft substrate 51 is wound on the substrate-supplying pulley 211 within the vacuum chamber 110. The material of the substrate 51 could be a fabric, a fiber, a paper or a polymer slice and so on.

A FIR target containing materials emitting FIR is prepared. The composition of the FIR materials is composed of the major composition of several natural minerals, which includes at least an aluminum oxide. Other composition of the FIR materials could include a titanium dioxide, a titanium boride or even more composition of the nature minerals, such as a magnesium oxide, an iron oxide, a zinc hydroxide and a carbide and so on.

The surface of the substrate with an ion bombardment pretreatment is processed. Most substrates, such as a fabric, a fiber, a paper or a polymer slice, have a hydrophobic property on their surfaces, where the property usually makes the moisture on the surfaces of the substrates insufficient and the adhesion of the FIR thin film 52 deposited on the surface 511 of the substrate 51 is poor accordingly. In order to improve the problem related to the low moisture on the surface 511 of the substrate 51 and the poor adhesion of the FIR thin film 52, the present invention provides a surface processing method with an ion source 311 to increase the adhesion between the substrate 51 and the FIR thin film 52 by generating hydrophilic functional groups on the substrate 51.

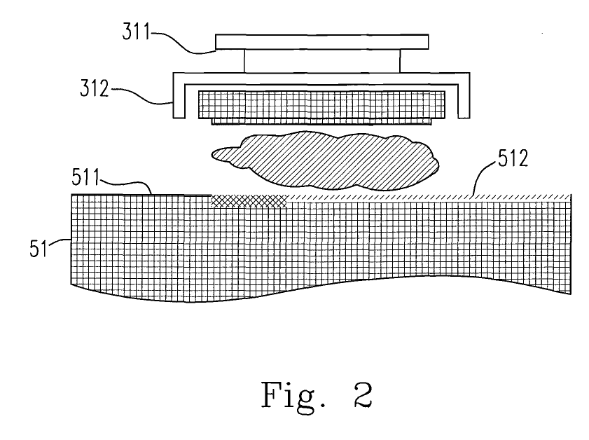

Please refer to FIG. 1 and FIG. 2. FIG. 2 is a diagram showing the surface processing method with an ion source according to the present invention. The substrate 51 wound on the substrate-supplying pulley 211 is transported to the first sputtering drum 2141 via the transport pulley set 21 for processing the surface of the substrate 51 by an ion source first. The vacuum pumping pipes 411-413 create a vacuum in the vacuum chamber 110, and then the mixture of the reaction gases oxygen and argon is introduced into the vacuum chamber 110 via the gas pipes 312 by a mass flow controller (MFC), wherein the flow rate of the reaction gases is controlled in a range of 10-200 c.c. per minute and the temperature within the vacuum chamber 110 is controlled around 25-100° C. depending on various substrates. Besides, the automatic pressure controlling system 4210 is actuated for maintaining a stable working pressure within the vacuum chamber 110 in a range of 10⁻⁴-10⁻¹ Torr. After supplying a high frequency (the intermediate frequency 40 MHz, the radio frequency 13.56 MHz and the microwave 2.54 GHz) power to the ion source 311, the reaction gas will dissociate in the ion source 311, and high energy density ion beam will be directed to the surface 511 of the substrate 51 to form a processed surface 512. The power could be a direct current (DC) power, a radio frequency power, a pulse direct current power or a microwave power.

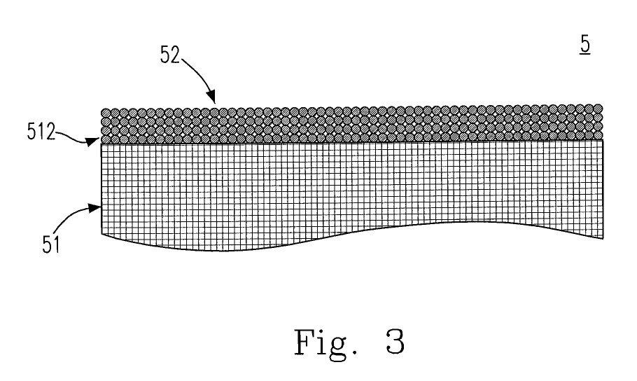

A FIR thin film 52 is formed. Please refer to FIG. 1 and FIG. 3, wherein FIG. 3 is a side view of the FIR substrate according to the present invention. After processing the surface of the substrate 51 by the ion source 311, the mixture of the reaction gases oxygen and argon is introduced into the vacuum chamber 110 via the gas pipe 3141 by the mass flow controller (MFC), wherein the temperature within the vacuum chamber 110 is controlled around 25-100° C. depending on various substrates and the working pressure within the vacuum chamber 110 is maintained preferably in a range of 10⁻⁴-10⁻¹ Torr by actuating the automatic pressure controlling system 4211 for performing the sputtering process. After supplying a radio frequency power to the sputtering source 3131, the radio frequency power will ionize the reaction gas mixture oxygen and argon. The dissociated ions with high energy will be attracted by the sputtering source 3131 and thereby strike the FIR target 3191 configured on the sputtering source 3131 so as to remove the FIR neutral atoms from the FIR target 3191 and deposit the FIR neutral atoms on the pretreated surface 512 of the substrate 51, which is passing through this sputtering region, on the first sputtering drum 2141 for forming the thin film 52. The FIR target 3191 has a power density larger than 38 W/cm². During the sputtering process for forming the FIR thin film 52, the polycold 321 condensates the residual water vapor in the vacuum chamber 110 so as to reduce the pumping time for creating a vacuum and to increase the yield of the FIR substrate. Besides, the polycold 321 also maintains a better growth condition for the FIR thin film and thus the adhesion between the FIR thin film and the pretreated surface 512 of the substrate 51 is better. If an ion source is used in the sputtering process (ion assisted sputtering), the FIR thin film 52 will have a higher deposition density and the FIR emissivity is increased accordingly.

If it is necessary to modulate the thickness of the FIR thin film 52 according to the applications of the FIR substrate 5, the FIR substrate 5 already processed around the first sputtering drum 2141 can be transported to the second sputtering drum 2142 by the substrate transporting guide pulleys 215 for another sputtering and for forming the FIR thin film 52 with continuous structure on the pretreated surface 512 of the substrate 51. The thickness of the FIR thin film 52 with continuous structure is in a range of 1 nanometer to 10 micrometer. In this preferred embodiment, four sputtering sources 3131, 3132, 3133, 3134 respectively cooperate with four gas pipes 3141, 3142, 3143, 3144, four FIR targets 3191, 3192, 3193, 3194 and four automatic pressure controlling systems 4211, 4212, 4213, 4214.

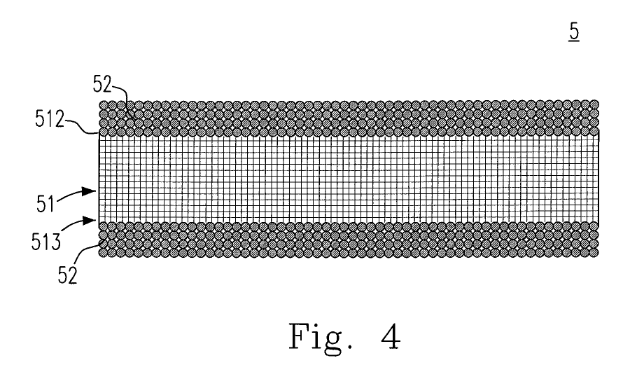

If it is necessary to deposit the FIR thin film 52 on both the two surfaces of the substrate 51, the soft substrate 51 could be rolled up in the reverse direction and be sputtered according to the above steps for manufacturing a FIR substrate 5 with respective FIR thin films 52 on the two processed surfaces 512, 513 of the substrate 51 (as shown in FIG. 4). Furthermore, the thickness of the FIR thin film 52 can be controlled by the rolling rate of the substrate rolling mechanism and the transporting rate of the transport pulley set 21 as well. The rolling rate is the moving rate of the substrate 51 passing through the first and the second sputtering drums 2141, 2142 in the sputtering region, wherein the moving rate could decide the required thickness of the FIR thin film 52. Therefore, the FIR thin film 52 is layered with at least one layer of the FIR materials and the transmittance of the FIR thin film 52 in the visible light range is in a range around 60˜99%, preferably in a range around 80˜99%.

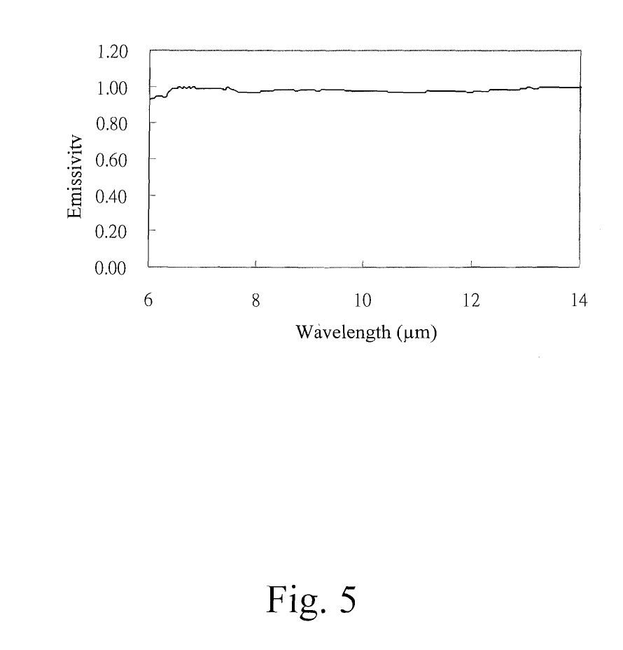

Please refer to FIG. 5, which is a diagram showing the FIR emissivity of the FIR materials according to the present invention. The FIR materials show a FIR emissivity, which is detected by a FIR spectrometer, of higher than 0.98 compared to the black body within the wavelength of 6 to 14 micron range. Besides, the FIR emission by the FIR materials has excellent antibacterial effects of over 99.9% both on Staphylococcus aureus (SA) and Escherichia coli (E-coli), which is evidenced by the recognized test protocol AATCC 100. Furthermore, the composition of the FIR materials used in the present invention comes from natural minerals, and it is confirmed by specific machines that the FIR materials are able to generate negative ions without any detectable ionizing radiation. So far, the ionizing radiation is still considered a possible carcinogen capable of causing all known types of genetic mutations. In order to increase the FIR emissivity, many FIR products contain too many rare elements, which cause the users to expose to high level of ionizing radiation from the FIR products without any realization. The present invention has high level of FIR emissivity without the consideration of the hazardous ionizing radiation.

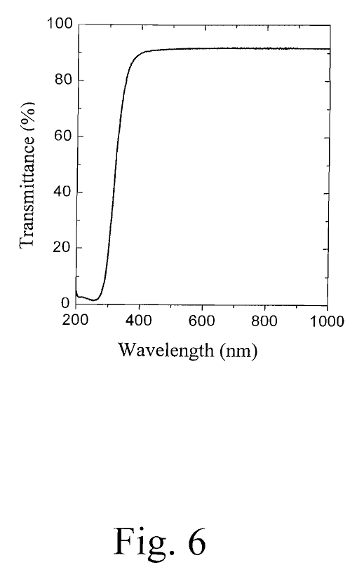

Please refer to FIG. 6, which is a diagram showing the transmittance of a FIR thin film according to the present invention. As shown, the transmittance of the FIR thin film 52 in the wavelength range of 400 to 1000 nm is averagely over 99%. Because of the important characteristic of the high transmittance, when the FIR thin film 52 of the preferred embodiment in the present invention is grown on the surface of the textile with polyester fibers, it will not affect the appearance of the textile and is able to be adhered uniformly to the surface of the textile.

The present invention provides a novel method for manufacturing a FIR textile. A sputtering system is used in this invention for manufacturing a transparent, uniform and continuous FIR thin film on the surface of a textile according to practical uses. The present invention improves the disadvantages existing in the prior arts, such as the content limitation of the FIR ceramic powder and the low adhesion resulting from large ceramic particles. The preferred embodiment according to the present invention is just one kind of sputtering process, which is suitable for soft substrates, and therefore it cannot be used to limit the application of the present invention. The method of the present invention can also be used to form a FIR thin film on the surfaces of other hard substrates, such as metal, glass and ceramics. One point of the present invention is that the method can be performed under room temperature. Most of the FIR ray related applications are textiles or polymer substrates, so the thin film coating processes for those substrates are unsuitable to be performed under high temperature because heat will deform some heat-sensitive textiles or deteriorate the original functions of the substrates. Accordingly, this point further reveals the importance of the present invention.

While the invention has been described in terms of what is presently considered to be the most practical and preferred embodiments, it is to be understood that the invention needs not be limited to the disclose embodiments. Therefore, it is intended to cover various modifications and similar arrangements included within the spirit and scope of the appended claims, which are to be accorded with the broadest interpretation so as to encompass all such modifications and similar structures.

What is claimed is:

1. A manufacturing method for a far-infrared (FIR) substrate, comprising the steps of:
providing a substrate; and
sputtering a FIR emission material onto the substrate.

2. The method as claimed in claim 1, wherein the sputtering step comprises the steps of:
(a) preparing a target containing the FIR emission material;
(b) providing a vacuum chamber and configuring a sputtering source in the vacuum chamber with the target placed on the sputtering source;
(c) configuring the substrate at a position opposite to the FIR emission material in the vacuum chamber;
(d) introducing a reaction gas into the vacuum chamber for igniting a plasma;
(e) applying a current for ionizing the reaction gas; and
(f) sputtering the FIR emission material on at least one surface of the substrate for forming a thin film.

3. The method as claimed in claim 2, wherein the sputtering further comprises the step of:
pretreating the surface of the substrate with an ionization.

4. The method as claimed in claim 2, wherein the sputtering step further comprises a step of:
controlling a flow rate of the reaction gas in a range of 10 to 200 c.c. per minute.

5. The method as claimed in claim 2, wherein the sputtering step further comprises a step of:
controlling a temperature within the vacuum chamber at a temperature ranging from 25 to 100° C.

6. The method as claimed in claim 2, wherein the step (b) further comprises a step of:
controlling a gas pressure within the vacuum chamber in a range of 10⁻¹ to 10⁻⁴ Torr.

7. The method as claimed in claim 2, wherein the reaction gas introduced in the step (d) is one selected from a group consisting of an argon, an oxygen and a combination thereof.

8. The method as claimed in claim 2, wherein the current in the step (e) is provided by one selected from a group consisting of a direct current power, a radio frequency power, a pulse direct current power and a microwave power.

9. The method as claimed in claim 2, wherein a thickness of the thin film is ranged from 1 nm to 10 μm.

10. The method as claimed in claim 2, wherein a transmittance of the thin film in a visible light range is in a range around 60˜99%.

11. The method as claimed in claim 10, wherein the transmittance of the thin film in a visible light range is in a range around 80˜99%.

12. The method as claimed in claim 2, wherein the thin film is layered with at least one layer of the FIR emission material.

13. The method as claimed in claim 1, wherein the substrate is one selected from a group consisting of a metal, a glass, a ceramic powder and a copolymer.

14. The method as claimed in claim 1, wherein the FIR emission material comprises an aluminum oxide.

15. The method as claimed in claim 1, wherein the FIR emission material has a far-infrared emissivity of higher than 0.9.

16. A manufacturing method for a far-infrared (FIR) substrate, comprising the steps of:
providing an ion bombardment pretreated substrate;
placing the ion bombardment pretreated substrate and a FIR material in a space filled with a gas; and
applying a current to the gas for forming the FIR substrate.

17. The method as claimed in claim 16, further comprising:
filling the gas in a rate of 10 to 200 c.c. per minute;
providing a temperature of the space ranged from 25 to 100° C.; and
providing a pressure of the space ranged from 10⁻¹ to 10⁻⁴ Torr.

18. The method as claimed in claim 17, wherein the gas is one selected from a group consisting of an argon, an oxygen, and a combination thereof, and the FIR material comprises an aluminum oxide.

19. The method as claimed in claim 16, further comprising:
forming a thin layer of the FIR material on the ion bombardment pretreated substrate after the current is applied.

20. The method as claimed in claim 19, wherein a thickness of the thin layer is ranged from 1 nm to 10 μm, and a transmittance of the thin layer is ranged from 80˜99%.
